(19) United States
(12) Patent Application Publication
(10) Pub. No.: US 2017/0271442 A1
(43) Pub. Date: Sep. 21, 2017

(54) SEMICONDUCTOR DEVICE

(71) Applicant: KABUSHIKI KAISHA TOSHIBA, Tokyo (JP)

(72) Inventor: Junichi UEHARA, Himeji Hyogo (JP)

(21) Appl. No.: 15/243,461

(22) Filed: Aug. 22, 2016

(30) Foreign Application Priority Data
Mar. 16, 2016 (JP) 2016-053105

(51) Int. Cl. H01L 29/06; H01L 21/04; H01L 29/78; H01L 29/66; H01L 29/16; H01L 29/10

(52) U.S. Cl. CPC H01L 29/0634; H01L 29/1608; H01L 29/1095; H01L 29/7802; H01L 29/66068; H01L 21/0465

(57) ABSTRACT

A semiconductor device includes a first electrode, a second electrode, and a silicon carbide layer. The silicon carbide layer includes a first conductivity type first region extending inwardly thereof. The impurity concentration of the first region increases in the depth direction of the silicon carbide layer. The silicon carbide layer includes a second conductivity type second region located adjacent to the first region and containing first and second conductivity type impurities. The concentration of the first conductivity type impurity in the second region increases in the depth direction of the silicon carbide layer. The silicon carbide layer includes a second conductivity type third region. The first region is located between the second region and the third region. The third region contains the first and second conductivity type impurities. The concentration of the first conductivity type impurity in the third region increases in the depth direction of the silicon carbide layer.

### CROSS-REFERENCE TO RELATED APPLICATION

This application is based upon and claims the benefit of priority from Japanese Patent Application No. 2016-053105, filed Mar. 16, 2016, the entire contents of which are incorporated herein by reference.

### FIELD

Embodiments described herein relate generally to a semiconductor device.

### BACKGROUND

Silicon carbide is expected to be a material of next-generation semiconductor devices. Silicon carbide has physical properties including a bandgap which is 3 times, a breakdown electric field strength which is about 10 times, and thermal conductivity which is about 3 times, that of silicon. When these characteristics are utilized, semiconductor devices capable of operating at low loss and at high temperature can be achieved.

As a structure for reducing the on resistance of a metal oxide semiconductor field effect transistor (MOSFET) using silicon carbide, there is a super-junction (hereinafter referred to as SJ) structure. In the SJ structure, n type regions and p type regions with a pillar shape are alternately and repeatedly arranged in a drift layer.

In the SJ structure, the impurity concentrations in the n type region and the p type region are uniform. At the time of turning off the MOSFET, a depletion layer is extended in the horizontal direction from a pn junction extending in the vertical direction at the interface of the n and the p type pillar shapes. By depleting both of the n type region and the p type region, it is possible to achieve high breakdown voltage. Conversely, at the time of turning on the MOSFET, on resistance is reduced by flowing a high concentration current through the n type region. The maintenance of high breakdown voltage and the reduction in the on resistance are compatible due to the SJ structure.

In a MOSFET having the SJ structure, device characteristics such as breakdown voltage or avalanche breakdown voltage change when the impurity concentration of the n type region or the p type region fluctuates due to a fluctuation of a manufacturing process. Accordingly, a MOSFET in which a variation in the device characteristics is suppressed due to a manufacturing process is desired.

### DESCRIPTION OF THE DRAWINGS

FIG. 1 is a schematic sectional view illustrating a semiconductor device according to an embodiment.

FIG. 2 is a schematic sectional view illustrating the semiconductor device which is being manufactured according to the embodiment.

FIG. 3 is a schematic sectional view illustrating a result of an intermediate step of manufacturing the semiconductor device according to the embodiment.

FIG. 4 is a schematic sectional view illustrating a result of an additional intermediate step of manufacturing the semiconductor device according to the embodiment.

FIG. 5 is a schematic sectional view illustrating the result of an additional intermediate step of manufacturing the semiconductor device according to the embodiment.

FIG. 6 is a schematic sectional view illustrating the result of an additional intermediate step of manufacturing the semiconductor device according to the embodiment.

FIG. 7 is a schematic sectional view illustrating the result of an additional intermediate step of manufacturing the semiconductor device according to the embodiment.

FIG. 8 is a schematic sectional view illustrating the result of an additional intermediate step of manufacturing the semiconductor device according to the embodiment.

FIG. 9 is a schematic sectional view illustrating the result of an additional intermediate step of manufacturing the semiconductor device according to the embodiment.

FIG. 10 is a diagram illustrating operations and advantages of the semiconductor device according to the embodiment.

### DETAILED DESCRIPTION

In general, according to one embodiment, a semiconductor device includes a first electrode, a second electrode, a silicon carbide layer, at least a portion of which is located between the first and second electrodes, a gate electrode, wherein at least a portion of the silicon carbide layer is located between the gate electrode and the second electrode, and a gate insulation film located between the gate electrode and the silicon carbide layer. The silicon carbide layer includes a first conductivity type first silicon carbide region extending from the gate insulating film inwardly of the silicon carbide layer, wherein the concentration of the first conductivity type impurity in the first conductivity type first silicon carbide region increases in the thickness direction of the silicon carbide layer extending away from the gate electrode. The silicon carbide layer further includes a second conductivity type second silicon carbide region located adjacent to the first conductivity type first silicon carbide region, wherein the second conductivity type second silicon carbide region contains the first conductivity type impurities and second conductivity type impurities, and wherein the concentration of the first conductivity type impurity in the second conductivity type second silicon carbide region increases in the thickness direction of the silicon carbide layer in the direction extending away from the gate electrode. The silicon carbide layer further includes a second conductivity type third silicon carbide region, wherein the first conductivity type first silicon carbide region is located between the second conductivity type second silicon carbide region and the second conductivity type third silicon carbide region, wherein the second conductivity type third silicon carbide region contains the first conductivity type impurities and the second conductivity type impurities, and wherein the concentration of the first conductivity type impurity in the second conductivity type third silicon carbide region increases in the thickness direction of the silicon carbide layer extending in the direction away from the gate electrode.

Hereinafter, an embodiment will be described with reference to the drawings. In the following description, the same reference numerals are given to same or similar members or the like and the description of the members or like described once will not be repeated where appropriate.

In the following description, notations of n⁺, n, n⁻, p⁺, p, and p⁻ indicate relative magnitude of the impurity concentration in a layer of the respective p or n conductivity type in a semiconductor layer such as silicon carbide. That is, the n type impurity concentration of n⁺ is higher than that of n, and the n type impurity concentration of n⁻ is lower than that of an “n” impurity concentration. Further, the p type impurity concentration of p⁺ is greater than that of a “p” type impurity concentration, and the p type impurity concentration of p⁻ is lower than that of a p impurity concentration. Furthermore, n⁺ and n⁻ types are simply written as the n type and p⁺ and p⁻ types are simply written as the p type in some cases.

An impurity concentration can be measured by, for example, using Secondary Ion Mass Spectrometry (SIMS). The relative magnitude of the impurity concentration can also be determined from the magnitude of a carrier concentration obtained by, for example, Scanning Capacitance Microscopy (SCM). A distance such as the depth of an impurity region can be obtained by, for example, the SIMS methodology. A distance such as the depth of an impurity region can be obtained from, for example, a combined image of an SCM image and an atomic force microscope (AFM) image.

### Embodiment

According to an embodiment, a semiconductor device includes: a first electrode; a second electrode; a silicon carbide layer of which at least a portion is formed between the first and second electrodes; a gate electrode that is formed such that the silicon carbide layer is located between the gate electrode and the second electrode; a gate insulation film that is formed between the gate electrode and the silicon carbide layer; a first-conductivity type first silicon carbide region that is formed in the silicon carbide layer between the gate electrode and the second electrode and includes a first first-conductivity type region and a second first-conductivity type region and in which the second first-conductivity type region is formed between the first first-conductivity type region and the second electrode, and a first conductivity type impurity concentration of the second first-conductivity type region is higher than the first conductivity type impurity concentration of the first first-conductivity type region; a second-conductivity type second silicon carbide region that is formed in the silicon carbide layer and contains first conductivity type impurities and second conductivity type impurities; a second-conductivity type third silicon carbide region that is formed in the silicon carbide layer, is formed such that the first silicon carbide region is located between the second silicon carbide region and the second-conductivity type third silicon carbide region, and contains the first conducive impurities and the second conductivity type impurities; a first-conductivity type fourth silicon carbide region that is formed in the silicon carbide layer between the first electrode and the second silicon carbide region and comes into contact with the first electrode and of which the first conductivity type impurity concentration is higher than the first conductivity type impurity concentration of the first silicon carbide region; and a first-conductivity type fifth silicon carbide region that is formed in the silicon carbide layer between the first electrode and the third silicon carbide region and comes into contact with the first electrode and of which the first conductivity type impurity concentration is higher than the first conducive impurity concentration of the first silicon carbide region.

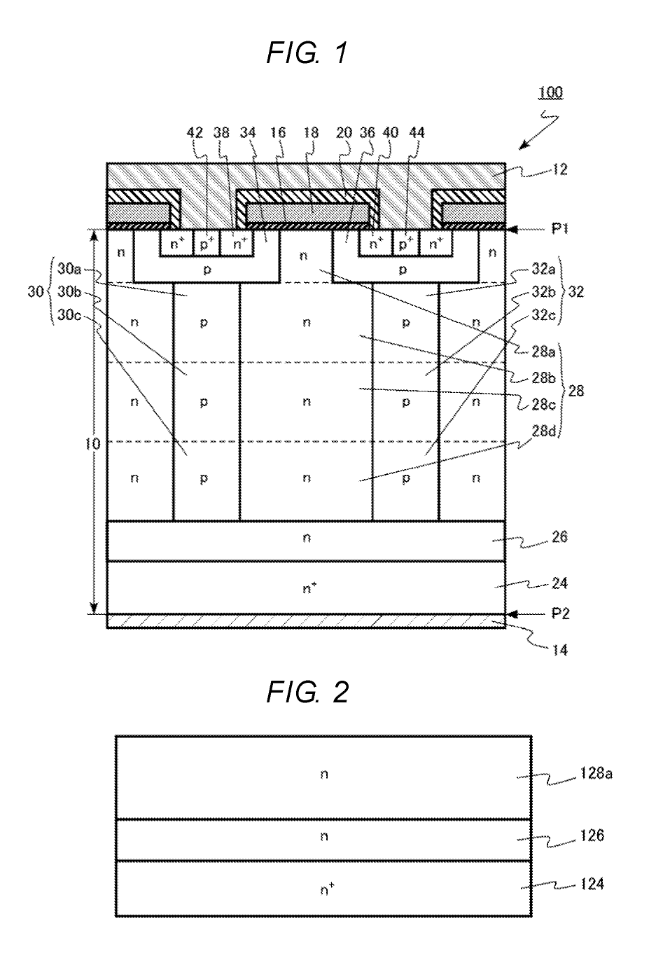

FIG. 1 is a schematic sectional view illustrating the semiconductor device according to an embodiment. The semiconductor device according to the embodiment is a planar gate type vertical MOSFET 100 having silicon carbide semiconductor layers therein. Hereinafter, a case in which a first conductivity type is an n type and a second conductivity type is a p type will be described.

The MOSFET 100 includes a silicon carbide layer 10, a source electrode 12, a drain electrode 14, a gate insulation film 16, a gate electrode 18, and an inter-layer insulation film 20.

The silicon carbide layer 10 includes both n and p type regions therein, including an n⁺ type drain region 24, an n type buffer region 26, an n type drift region (first silicon carbide region) 28, a first p type pillar region (second silicon carbide region) 30, a second p type pillar region (third silicon carbide region) 32, a p type first body region (sixth silicon carbide region) 34, a p type second body region (seventh silicon carbide region) 36, an n⁺ type first source region (fourth silicon carbide region) 38, an n⁺ type second source region (fifth silicon carbide region) 40, a p⁺ type first body contact region 42, and a p⁺ type second body contact region 44 therein.

The n type drift region (first silicon carbide region) 28 includes a surface n type region 28a, a first n type region (first first-conductivity type region) 28b, a second n type region (second first-conductivity type region) 28c, and a third n type region (third first-conductivity type region) 28d. The first n type region 28b, the second n type region 28c, and the third n type region 28d in the drift region 28 form an n type pillar region.

The first p type pillar region (second silicon carbide region) 30 includes a first p type region (first second-conductivity type region) 30a, a second p type region (second second-conductivity type region) 30b, and a third p type region 30c.

The second p type pillar region (third silicon carbide region) 32 includes a first p type region (third second-conductivity type region) 32a, a second p type region (fourth second-conductivity type region) 32b, and a third p type region 32c.

The n type pillar regions in the drift region 28, the first p type pillar region 30, and the second p type pillar region 32 forma portion of the SJ structure. The first p type pillar region 30 is interposed between two n type pillar regions. The second p type pillar region 32 is also interposed between two n type pillar regions. The n type pillar regions and the p type pillar regions are alternately arranged along the silicon carbide layer 10 to the right and to the left of FIG. 1 to form the SJ structure.

At least a portion of the silicon carbide layer 10 is formed between the source electrode 12 and the drain electrode 14. The silicon carbide layer 10 is, in the embodiment, monocrystalline SiC. The silicon carbide layer 10 is, for example, 4H-SiC.

The silicon carbide layer 10 has a first surface (“P1” in FIG. 1) and a second surface (“P2” in FIG. 1). Hereinafter, the first surface is also referred to as a front surface and the second surface is also referred to as a rear surface. Hereinafter, a “depth” means a depth measured using the first surface as the zero location or measurement baseline.

The first surface is, for example, a surface inclined at 0 degrees or more and 8 degrees or less with respect to a (0001) surface of the SiC lattice structure. The second surface is, for example, a surface inclined at 0 degrees or more and 8 degrees or less with respect to a (000-1) surface of the SiC lattice structure. The (0001) surface is referred to as a silicon surface. The (000-1) surface is referred to as a carbon surface.

The n⁺ type drain region 24 is formed on the rear surface side of the silicon carbide layer 10. The drain region 24 contains, for example, nitrogen (N) as an n type impurity. The impurity concentration of the n type impurities in the drain region 24 is, for example, 1×10¹⁸ cm⁻³ or more and 1×10²¹ cm⁻³ or less.

The n type buffer region 26 is formed over the drain electrode 14 with the drain region 24 interposed therebetween. The buffer region 26 has a function of reducing a crystal defect density in the drift region 28 when the drift region 28 is formed on the drain region 24 by epitaxial growth.

The impurity concentration of the n type impurities in the n type buffer region 26 is lower than the impurity concentration of the n type impurities in the drain region 24. The buffer region 26 contains, for example, nitrogen (N) as the n type impurity. The impurity concentration of the n type impurities of the buffer region 26 is, for example, 5×10¹⁷ cm⁻³ or more and 5×10¹⁸ cm⁻³ or less.

The n type drift region 28 is formed in the silicon carbide layer 10. The drift region 28 is formed between the gate insulation film 16 and the drain electrode 14. The drift region 28 is formed on the buffer region 26.

The drift region 28 includes the surface n type region 28a, the first n type region 28b, the second n type region 28c, and the third n type region 28d. The surface n type region 28a contacts the gate insulation film 16. The first n type region 28b is formed between the surface n type region 28a and the drain electrode 14. The second n type region 28c is formed between the first n type region 28b and the drain electrode 14. The third n type region 28d is formed between the second n type region 28c and the drain electrode 14.

The drift region 28 contains, for example, nitrogen (N) as the n type impurity. The impurity concentration of the n type impurities in the drift region 28 is lower than the impurity concentration of the n type impurities in the drain region 24.

The impurity concentration of the n type impurities in the first n type region 28b is higher than the impurity concentration of the n type impurities in the surface n type region 28a. The impurity concentration of the n type impurities in the second n type region 28c is higher than the impurity concentration of the n type impurities in the first n type region 28b. The impurity concentration of the n type impurities in the third n type region 28d is higher than the impurity concentration of the n type impurities in the second n type region 28c. Thus, the n type impurity concentration in the drift region 28 increases in the direction from the front surface P1 to the rear surface P2. In other words, the n type impurity concentration in the drift region 28 increases in the depth direction of the device.

The impurity concentration of the n type impurities in the drift region 28 is, for example, 5×10¹⁵ cm⁻³ or more and 5×10¹⁸ cm⁻³ or less. The impurity concentration of the n type impurities in the surface n type region 28a is, for example, 5×10¹⁵ cm⁻³ or more and 5×10¹⁶ cm⁻³ or less. The impurity concentration of the n type impurities in the first n type region 28b is, for example, 1×10¹⁶ cm⁻³ or more and 1×10¹⁷ cm⁻³ or less. The impurity concentration of the n type impurities in the second n type region 28c is, for example, 1×10¹⁷ cm⁻³ or more and 1×10¹⁸ cm⁻³ or less. The impurity concentration of the n type impurities in the third n type region 28d is, for example, 5×10¹⁷ cm⁻³ or more and 5×10¹⁸ cm⁻³ or less.

The thickness of the drift region 28 is, for example, 5 μm or more and 150 μm or less.

The first p type pillar region 30 is formed in the silicon carbide layer 10. The first p type pillar region 30 is formed on the buffer region 26. The first p type pillar region 30 may be formed only in the drift region 28 so that the first p type pillar region 30 does not come into contact with the buffer region 26.

The first p type pillar region 30 includes the first p type region 30a, the second p type region 30b, and the third p type region 30c. The second p type region 30b is formed between the first p type region 30a and the drain electrode 14. The third p type region 30c is formed between the second p type region 30b and the drain electrode 14.

The first p type pillar region 30 contains n type impurities and p type impurities. The impurity concentration of the p type impurities is higher than the impurity concentration of the n type impurities. The n type impurities are, for example, nitrogen (N). The p type impurities are, for example, aluminum (Al).

The impurity concentration of the n type impurities of the first p type pillar region 30 is, for example, 5×10¹⁵ cm⁻³ or more and 5×10¹⁸ cm⁻³ or less. The impurity concentration of the p type impurities of the first p type pillar region 30 is, for example, 1×10¹⁸ cm⁻³ or more and 5×10¹⁹ cm⁻³ or less.

The difference between the impurity concentration of the p type impurities and the impurity concentration of the n type impurities in the first p type region 30a is greater than the difference between the impurity concentration of the p type impurities and the impurity concentration of the n type impurities in the second p type region 30b. The difference between the impurity concentration of the p type impurities and the impurity concentration of the n type impurities in the second p type region 30b is greater than the difference between the impurity concentration of the p type impurities and the impurity concentration of the n type impurities in the third p type region 30c.

The impurity concentration of the p type impurities of the first p type pillar region 30 in the depth direction is substantially constant. The impurity concentration of the p type impurities of the first p type pillar region 30 in the depth direction is constant within a range of production tolerance. The tolerance range of the impurity concentration of the p type impurities of the first p type pillar region 30 in the depth direction is, for example, within ±20%.

The second p type pillar region 32 is also formed in the silicon carbide layer 10. The second p type pillar region 32 is formed on the buffer region 26. The second p type pillar region 32 may be formed only in the drift region 28 so that the second p type pillar region 32 does not come into contact with the buffer region 26.

The drift region 28 is located between the second p type pillar region 32 and the first p type pillar region 30. The first n type region 28b, the second n type region 28c, and the third n type region 28d are sequentially interposed between the second p type pillar region 32 and the first p type pillar region 30.

The second p type pillar region 32 includes the first p type region 32a, the second p type region 32b, and the third p type region 32c. The second p type region 32b is formed between the first p type region 32a and the drain electrode 14. The third p type region 32c is formed between the second p type region 32b and the drain electrode 14.

The first n type region (first first-conductivity type region) 28b is located between the first p type region (first second-conductivity type region) 30a and the first p type region (third second-conductivity type region) 32a. The second n type region (second first-conductivity type region) 28c is located between the second p type region (second second-conductivity type region) 30b and the second p type region (fourth second-conductivity type region) 32b. The third n type region (third first-conductivity type region) 28d is located between the third p type region 30c and the third p type region 32c.

The second p type pillar region 32 contains n type impurities and p type impurities. The impurity concentration of the p type impurities is higher than the impurity concentration of the n type impurities. The n type impurities are, for example, nitrogen (N). The p type impurities are, for example, aluminum (Al).

The impurity concentration of the n type impurities of the second p type pillar region 32 is, for example, 5×10¹⁵ cm⁻³ or more and 5×10¹⁸ cm⁻³ or less. The impurity concentration of the p type impurities of the second p type pillar region 32 is, for example, 1×10¹⁸ cm⁻³ or more and 5×10¹⁹ cm⁻³ or less.

The difference between the impurity concentration of the p type impurities and the impurity concentration of the n type impurities in the first p type region 32a is greater than the difference between the impurity concentration of the p type impurities and the impurity concentration of the n type impurities in the second p type region 32b. The difference between the impurity concentration of the p type impurities and the impurity concentration of the n type impurities in the second p type region 32b is greater than the difference between the impurity concentration of the p type impurities and the impurity concentration of the n type impurities in the third p type region 32c.

The impurity concentration of the p type impurities of the second p type pillar region 32 in the depth direction is substantially constant. The impurity concentration of the p type impurities of the second p type pillar region 32 in the depth direction is constant within a range of production tolerance. The tolerance range of the impurity concentration of the p type impurities of the second p type pillar region 32 in the depth direction is, for example, within ±20%.

The impurity concentration of the p type impurities of the second p type pillar region 32 and the impurity concentration of the p type impurities of the first p type pillar region 30 are substantially the same. The impurity concentration of the p type impurities of the second p type pillar region 32 and the impurity concentration of the p type impurities of the first p type pillar region 30 are the same within the range of production tolerance.

The p type first body region 34 is formed in the silicon carbide layer 10. The first body region 34 is located between the source electrode 12 and the drift region 28. The first body region 34 is thus located between the source electrode 12 and the first p type pillar region 30. The first body region 34 also contacts the gate insulation film 16 to either side of the first source region 38. The first body region 34 functions as a channel region of the MOSFET 100.

The first body region 34 contains, for example, aluminum (Al) as the p type impurity. The impurity concentration of the p type impurities in the first body region 34 is, for example, 1×10¹⁷ cm⁻³ or more and 1×10¹⁸ cm⁻³ or less. The depth of the first body region 34 is, for example, 0.3 μm or more and 0.8 μm or less.

The p type second body region 36 is formed in the silicon carbide layer 10. The second body region 36 is formed between the source electrode 12 and the drift region 28. The second body region 36 is formed between the source electrode 12 and the second p type pillar region 32. The second body region 36 contacts the gate insulation film 16 to either side of the second source region 40. The second body region 36 functions as a channel region of the MOSFET 100.

The second body region 36 contains, for example, aluminum (Al) as the p type impurity. The impurity concentration of the p type impurities in the second body region 36 is, for example, 1×10¹⁷ cm⁻³ or more and 1×10¹⁸ cm⁻³ or less. The depth of the second body region 36 is, for example, 0.3 μm or more and 0.8 μm or less.

The n⁺ type first source region 38 is formed in the silicon carbide layer 10. The first source region 38 is formed between the source electrode 12 and the first p type pillar region 30. The first source region 38 is formed between the source electrode 12 and the first body region 34. The first source region 38 contacts the source electrode 12.

The first source region 38 contains, for example, phosphorus (P) as the n type impurity. The impurity concentration of the n type impurity in the first source region 38 is higher than the impurity concentration of the n type impurities in the drift region 28.

The impurity concentration of the n type impurities of the first source region 38 is, for example, 1×10¹⁹ cm⁻³ or more and 1×10²¹ cm⁻³ or less. The depth of the first source region 38 is shallower than the depth of the first body region 34 and is, for example, 0.1 μm or more and 0.3 μm or less.

The n⁺ type second source region 40 is formed in the silicon carbide layer 10. The second source region 40 is formed between the source electrode 12 and the second p type pillar region 32. The second source region 40 is formed between the source electrode 12 and the second body region 36. The second source region 40 contacts the source electrode 12.

The second source region 40 contains, for example, phosphorus (P) as the n type impurity. The impurity concentration of the n type impurity in the second source region 40 is higher than the impurity concentration of the n type impurities in the drift region 28.

The impurity concentration of the n type impurities in the second source region 40 is, for example, 1×10¹⁹ cm⁻³ or more and 1×10²¹ cm⁻³ or less. The depth of the second source region 40 is shallower than the depth of the second body region 36 and is, for example, 0.1 μm or more and 0.3 μm or less.

The p⁺ type first body contact region 42 is formed between the source electrode 12 and the first body region 34. The first body contact region 42 contacts the source electrode 12. The impurity concentration of the p type impurities in the first body contact region 42 is higher than the impurity concentration of the p type impurities in the first body region 34.

The first body contact region 42 contains, for example, aluminum (Al) as the p type impurity. The impurity concentration of the p type impurities in the first body contact region 42 is, for example, 1×10¹⁹ cm⁻³ or more and 1×10²¹ cm⁻³ or less.

The depth of the first body contact region 42 is, for example, 0.1 μm or more and 0.3 μm or less.

The p⁺ type second body contact region 44 is formed between the source electrode 12 and the second body region 36. The second body contact region 44 contacts the source electrode 12. The impurity concentration of the p type impurities in the second body contact region 44 is higher than the impurity concentration of the p type impurities in the second body region 36.

The second body contact region 44 contains, for example, aluminum (Al) as the p type impurity. The impurity concentration of the p type impurities in the second body contact region 44 is, for example, 1×10¹⁹ cm⁻³ or more and 1×10²¹ cm⁻³ or less.

The depth of the second body contact region 44 is, for example, 0.1 μm or more and 0.3 μm or less.

The gate electrode 18 is formed on the gate insulation film 16. The silicon carbide layer 10 is located between the gate insulation film 16 and the drain electrode 14.

The gate electrode 18 is an impurity type doped layer. The gate electrode 18 is, for example, polycrystalline silicon that contains p type impurities or n type impurities.

The gate insulation film 16 is formed between the gate electrode 18 and the silicon carbide layer 10. The gate insulation film 16 is formed between the gate electrode 18 and the first body region 34. The gate insulation film 16 is formed between the gate electrode 18 and the second body region 36.

The gate insulation film 16 is, for example, a silicon oxide film. For example, a High-k insulation film (high-permittivity insulation film) can be applied to the gate insulation film 16.

The inter-layer insulation film 20 is formed on the gate electrode 18. The inter-layer insulation film 20 is, for example, a silicon oxide film. The inter-layer insulation film 20 is formed between the source electrode 12 and the gate electrode 18.

The source electrode 12 contacts the first source region 38, the first body contact region 42, the second source region 40, and the second body contact region 44. A silicide region (not illustrated) containing silicide is formed where the source electrode 12 contacts the first source region 38, the first body contact region 42, the second source region 40, and the second body contact region 44.

The source electrode 12 contains metal. The metal forming the source electrode 12 is, for example, a stacked structure of titanium (Ti) and aluminum (Al). The silicide region is a metal silicide. The silicide region is, for example, a titanium silicide or a nickel silicide.

The drain electrode 14 is formed on the rear surface of the silicon carbide layer 10. The drain electrode 14 comes into contact with the drain region 24.

The drain electrode 14 contains, for example, a metal or a metal semiconductor compound. The drain electrode 14 contains, for example, a material selected from a group consisting of nickel silicide, titanium (Ti), nickel (Ni), silver (Ag), and gold (Au).

Next, a method of manufacturing the MOSFET 100 according to the embodiment will be described. FIGS. 2 to 9 are schematic sectional views illustrating the semiconductor device which is being manufactured according to the embodiment.

First, an n type first silicon carbide layer 126 is formed on an n⁺ type silicon carbide substrate 124. The first silicon carbide layer 126 is formed by epitaxial growth on the n⁺ type silicon carbide substrate 124. The n⁺ type silicon carbide substrate 124 serves as the drain region 24 of the MOSFET 100. The first silicon carbide layer 126 serves as the buffer region 26 of the MOSFET 100.

Next, an n type second silicon carbide layer 128a is formed on the first silicon carbide layer 126 (see FIG. 2). The second silicon carbide layer 128a is formed by epitaxial growth on the first silicon carbide layer 126.

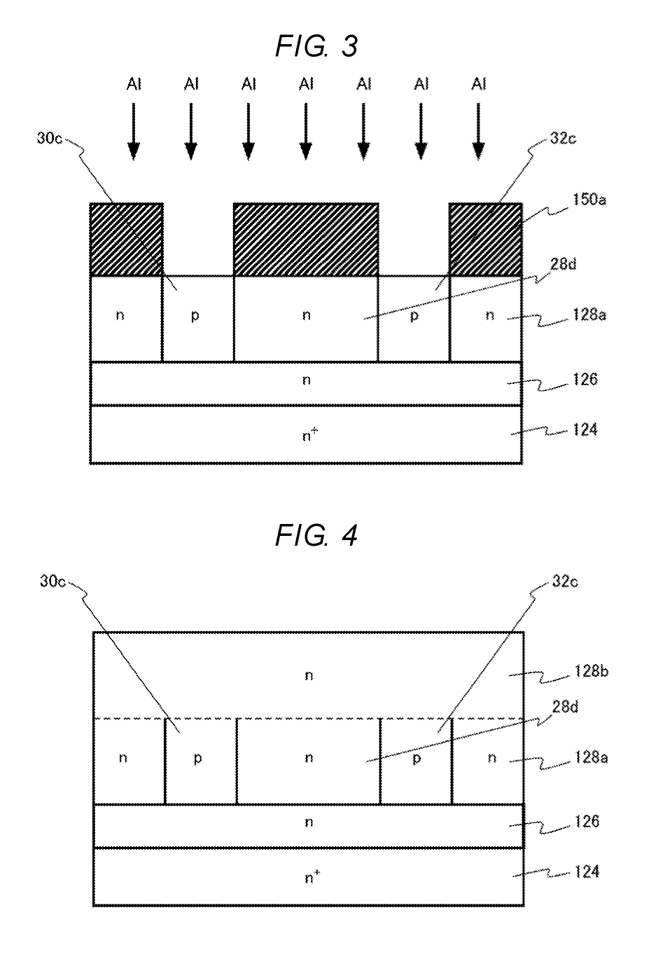

Next, aluminum (Al) is ion-implanted into the second silicon carbide layer 128a as the p type impurities using a mask material 150a as a mask (see FIG. 3). The mask material 150a is, for example, a silicon oxide film subjected to patterning.

By introducing the p type impurities into the second silicon carbide layer 128a, the third p type region 30c and the third p type region 32c are formed. A region between the third p type region 30c and the third p type region 32c serves as the third n type region 28d. Both of n type impurities and p type impurities are contained in the third p type region 30c and the third p type region 32c.

Next, an n type third silicon carbide layer 128b is formed on the second silicon carbide layer 128a (see FIG. 4). The third silicon carbide layer 128b is formed by epitaxial growth on the second silicon carbide layer 128a. The impurity concentration of the n type impurities in the third silicon carbide layer 128b is lower than the impurity concentration of the n type impurities of the second silicon carbide layer 128a.

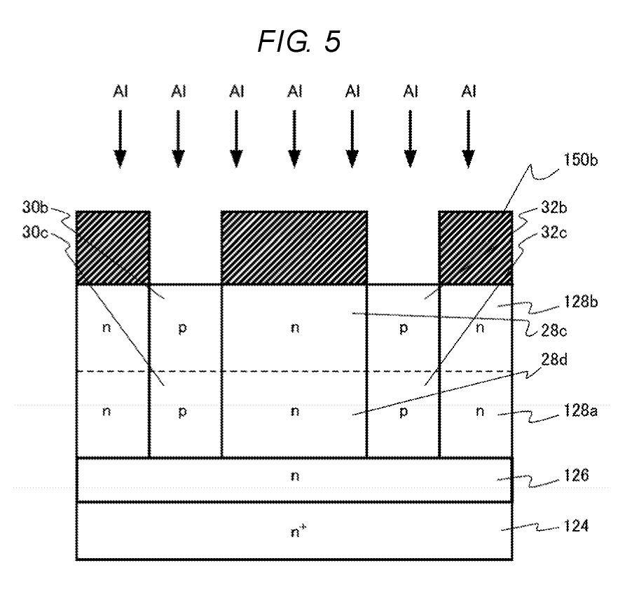

Next, aluminum (Al) is ion-implanted as a p type impurity into the third silicon carbide layer 128b using a mask material 150b as a mask (see FIG. 5). The mask material 150b is, for example, a silicon oxide film subjected to patterning.

By introducing the p type impurities into the n type third silicon carbide layer 128b, the second p type region 30b and the second p type region 32b are formed. A region between the second p type region 30b and the second p type region 32b serves as the second n type region 28c. Both the n type impurities and the p type impurities are contained in the second p type region 30b and the second p type region 32b.

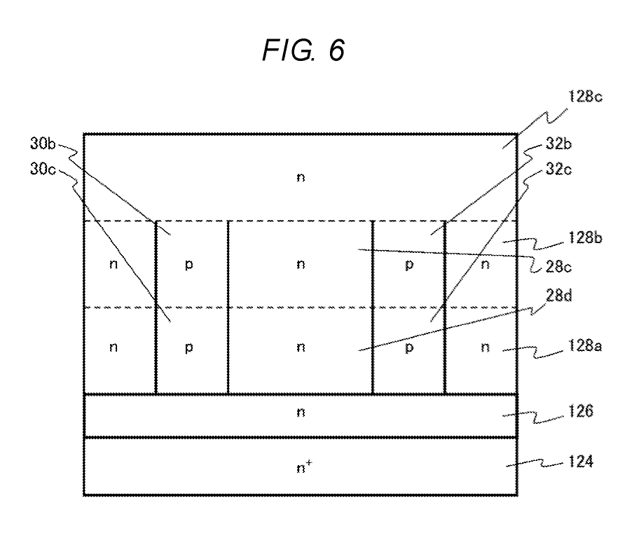

Next, an n type fourth silicon carbide layer 128c is formed on the third silicon carbide layer 128b (see FIG. 6). The fourth silicon carbide layer 128c is formed by epitaxial growth on the third silicon carbide layer 128b. The impurity concentration of the n type impurities in the fourth silicon carbide layer 128c is lower than the impurity concentration of the n type impurities in the third silicon carbide layer 128b.

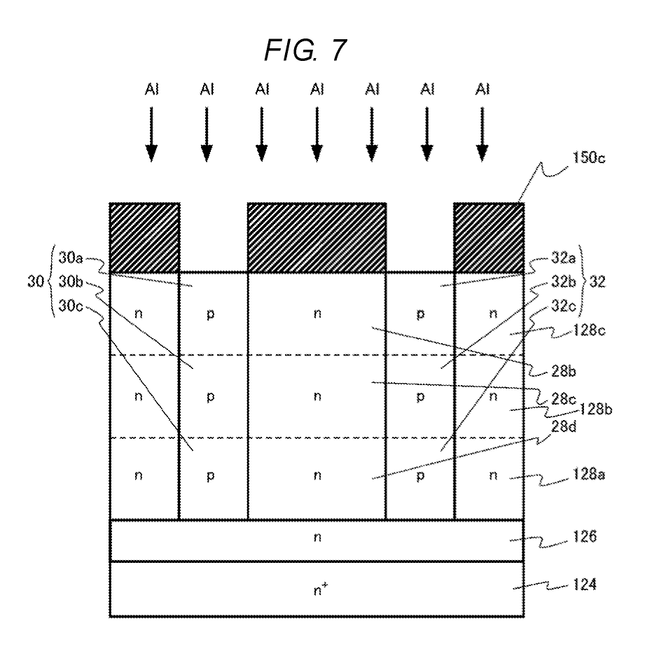

Next, aluminum (Al) is ion-implanted as the p type impurity into the fourth silicon carbide layer 128c using a mask material 150c as a mask (see FIG. 7). The mask material 150c is, for example, a silicon oxide film subjected to patterning.

By introducing the p type impurities into the n type fourth silicon carbide layer 128c, the first p type region 30a and the first p type region 32a are formed. The region between the first p type region 30a and the first p type region 32a serves as the first n type region 28b. Both of the n type impurities and the p type impurities are contained in the first p type region 30a and the first p type region 32a.

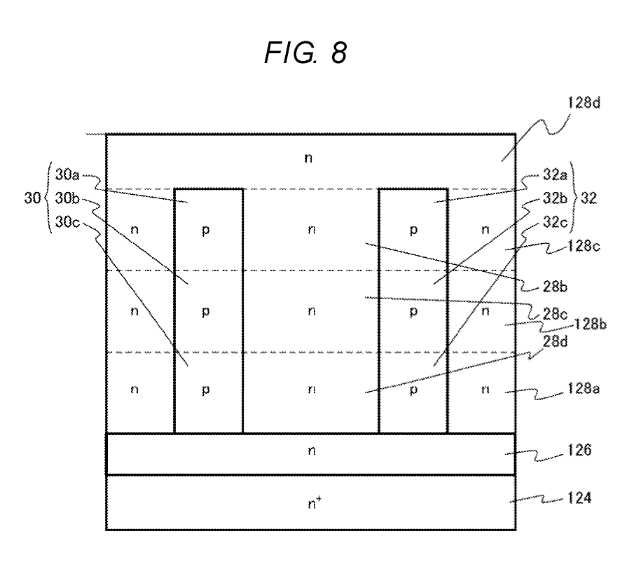

Next, an n type fifth silicon carbide layer 128d is formed on the fourth silicon carbide layer 128c (see FIG. 8). The fifth silicon carbide layer 128d is formed by epitaxial growth fourth silicon carbide layer 128c. The impurity concentration of the n type impurities in the fifth silicon carbide layer 128d is lower than the impurity concentration of the n type impurities in the fourth silicon carbide layer 128c.

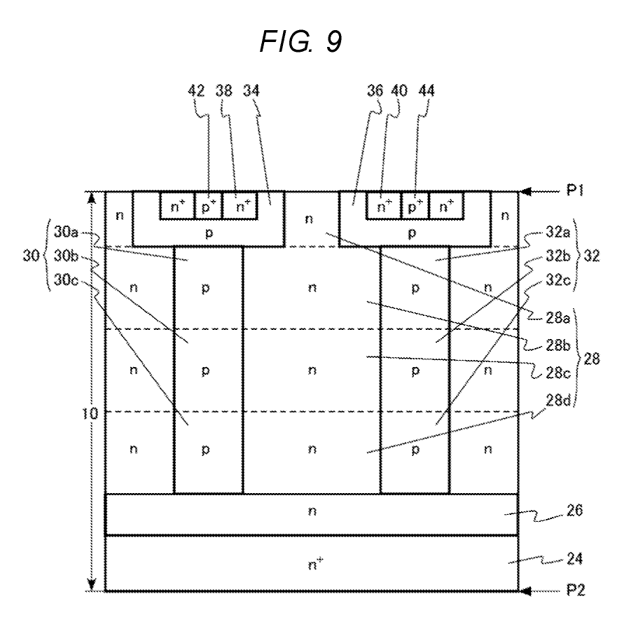

Next, p type impurities and n type impurities are ion-implanted into the fifth silicon carbide layer 128d using a mask (not illustrated) (see FIG. 9). By introducing the p type impurities and the n type impurities into the fifth silicon carbide layer 128d, the p type first body region 34, the p type second body region 36, the n⁺ type first source region 38, the n⁺ type second source region 40, the p⁺ type first body contact region 42, and the p⁺ second body contact region 44 are formed. A region between the first body region 34 and the second body region 36 serves as the surface n type region 28a.

Thereafter, according to a known manufacturing method, the source electrode 12, the drain electrode 14, the gate insulation film 16, the gate electrode 18, and the inter-layer insulation film 20 are formed. The MOSFET 100 according to the embodiment is formed according to the above manufacturing method.

Hereinafter, operations and advantages of the semiconductor device according to the embodiment will be described.

In a MOSFET having the SJ structure, there is a concern that the impurity concentration of the n type region or the p type region may fluctuate (change) due to a fluctuation of a manufacturing process from layer to layer or manufactured device to manufactured device. Device characteristics such as breakdown voltage or avalanche breakdown voltage change when the impurity concentration of the n type region or the p type region fluctuates. Accordingly, a MOSFET in which the device characteristics are different due to a manufacturing process is expected to be created.

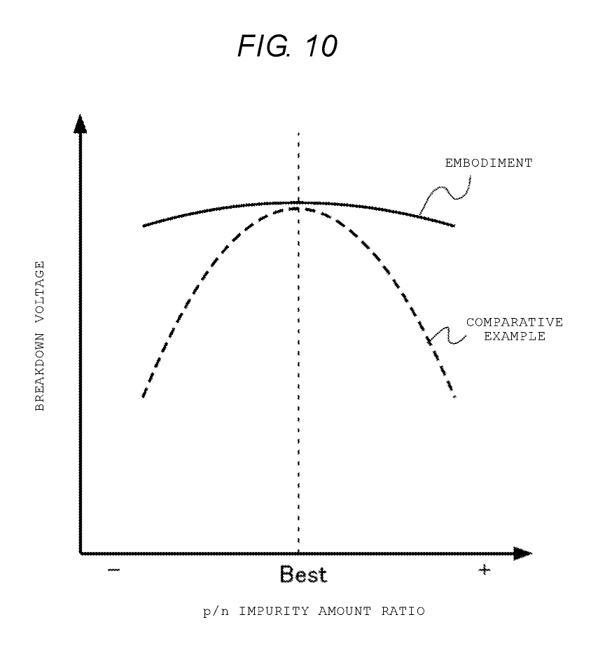

FIG. 10 is a diagram illustrating the operations and advantages of the semiconductor device according to the embodiment. FIG. 10 schematically illustrates the variation in the breakdown voltage when the ratio (p/n impurity amount ratio) of a p type impurity amount (p type charge amount) to an n type impurity amount (n type charge amount) is varied in the SJ structure. A p/n type impurity amount ratio at which the breakdown voltage is the highest is referred to as “Best”, a case in which the p type impurity amount increases with respect to the n-type impurities is expressed to be positive (+), and a direction in which the n type impurity amount increases with respect to the p type impurity is expressed to be negative (−).

In a MOSFET according to a comparative example, the impurity concentration of the n type impurities in the depth direction of the drift region is constant. As illustrated in FIG. 10, the breakdown voltage is lowered when the p/n impurity amount ratio swings in the positive or negative direction.

In the MOSFET 100 according to the embodiment, the impurity concentration of the n type impurities in the depth direction of the drift region increases in the depth direction. When a voltage is applied between the source electrode and the drain electrode at the time of turning off the MOSFET 100, a depletion layer growing in the horizontal direction from a pn junction begins to come into contact from the p type pillar region on the source side on which the impurity concentration of the n type impurities is low. Thereafter, the depletion layer spreads on the drain side.

When the depletion layer spreads on the drain side, the electric field concentration on the upper and lower ends of the pillar region lowers. Therefore, avalanche breakdown voltage easily occurs on the lower side of the pillar region, that is, the drain side of the SJ structure. Accordingly, the avalanche breakdown voltage can be increased.

In a structure in which the impurity concentration of the n type impurities in the depth direction of the drift region increases in the depth direction, as illustrated in FIG. 10, the dependency of a value of the breakdown voltage on the p/n type impurity amount ratio is less than in the comparative example. This is because even when the p/n impurity amount ratio of the pillar region is changed, electric field concentration rarely occurs in the upper and lower ends of the pillar region, and thus the breakdown voltage does not significantly decrease when the p/n ratio changes.

Accordingly, the variation in the breakdown voltage caused due to a manufacturing process decreases. Accordingly, the MOSFET 100 having the SJ structure in which a variation in the device characteristics are suppressed due to a manufacturing process is achieved.

In the MOSFET 100 according to the embodiment, the first p type pillar region 30 and the second p type pillar region contain n type impurities in addition to the p type impurities. Since n type impurities coexist in p type silicon carbide, a trimer of N—Al—N is formed and as a result the activation ratio of the p type impurities increases. Accordingly, specific resistance of the p type silicon carbide decreases more than when the n type impurities do not coexist therewith.

Accordingly, in the MOSFET 100 according to the embodiment, the first p type pillar region 30 and the second p type pillar region 32 with small resistance can be achieved. Since the resistance of the first p type pillar region 30 and the second p type pillar region 32 is decreased, extraction of electron holes at the time of occurrence of avalanche breakdown voltage is accelerated. Accordingly, a destruction current (L load resistance) at the time of a switching operation is improved, and a MOSFET 100 with large avalanche breakdown voltage is achieved.

From the viewpoint of an increase in the activation ratio of the p type impurities, it is desirable that the n type impurities are nitrogen (N) and the p type impurities are aluminum (Al).

In a region of the p/n ratio toward the positive side of the horizontal axis from the “best” location in FIG. 10, a prominent overcurrent rarely occurs in the MOSFET at the time of a switching operation. Accordingly, by increasing the impurity concentration of the n type impurities in the depth direction of the drift region as the depth is deeper and designing the p/n impurity amount ratio on the positive side, a destruction current (L load resistance) at the time of a switching operation is improved, and the MOSFET 100 with large avalanche breakdown voltage is achieved.

From the viewpoint of a further decrease in a variation in the breakdown voltage caused due variation in the manufacturing process, the p type concentration (the difference between the p type impurity concentration and the n type impurity concentration) in the first p type pillar region 30 and the second p type pillar region 32 preferably increases toward the front surface.

In the embodiment, the difference between the impurity concentration of the p type impurities and the impurity concentration of the n type impurities in the first p type region 30a is greater than the difference between the impurity concentration of the p type impurities and the impurity concentration of the n type impurities in the second p type region 30b. Further, the difference between the impurity concentration of the p type impurities and the impurity concentration of the n type impurities in the second p type region 30b is greater than the difference between the impurity concentration of the p type impurities and the impurity concentration of the n type impurities in the third p type region 30c. Accordingly, the p type concentration of the first p type pillar region 30 increases toward the front surface.

In the embodiment, the difference between the impurity concentration of the p type impurities and the impurity concentration of the n type impurities in the first p type region 32a is greater than the difference between the impurity concentration of the p type impurities and the impurity concentration of the n type impurities in the second p type region 32b. Further, the difference between the impurity concentration of the p type impurities and the impurity concentration of the n type impurities in the second p type region 32b is greater than the difference between the impurity concentration of the p type impurities and the impurity concentration of the n type impurities in the third p type region 32c. Accordingly, the p type concentration of the second p type pillar region 32 increases toward the front surface.

As described above, according to the embodiment, it is possible to provide the MOSFET 100 capable of suppressing variation in the device characteristics caused by variations in the manufacturing process. Further, it is possible to provide the MOSFET 100 with large avalanche breakdown voltage.

In the embodiment, the impurity concentration of the n type impurities in the depth direction of the drift region 28 changes discontinuously as an example, in the embodiment in a stepwise manner as described above. However, of course, the impurity concentration of the n type impurities in the depth direction of the drift region 28 may change continuously.

In the embodiment, the planar gate type MOSFET 100 is exemplified, as described above. However, an embodiment can be applied to a trench gate type MOSFET provided in a trench gate in which a gate electrode is formed in a silicon carbide layer.

In the embodiment, a case of a 4H-Sic semiconductor material is exemplified as the crystalline structure of SiC, as described above. However, an embodiment can also be applied to a device using SiC of other crystalline structure, such as 6H-SiC, 3C-SiC, or the like. A surface other than the (0001) surface can also be used as the front surface of the silicon carbide layer 10.

In the embodiment, the first conductivity type is referred to as the n type and the second conductivity type is referred to as the p type as an example, as described above. However, the first conductivity type can be referred to as the p type and the second conductivity type can be referred to as the n type.

In the embodiment, aluminum (Al) is exemplified as the p type impurity, as described above. Boron (B) can also be used. Further, nitrogen (N) and phosphorous (P) are exemplified as the n type impurity, as described above. However, arsenic (As), antimony (Sb), or the like can also be applied.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
a silicon carbide layer, at least a portion of which is located between the first and second electrodes;
a gate electrode, wherein at least a portion of the silicon carbide layer is located between the gate electrode and the second electrode; and
a gate insulation film located between the gate electrode and the silicon carbide layer,
wherein the silicon carbide layer comprises:
a first conductivity type first silicon carbide region extending from the gate insulating film inwardly of the silicon carbide layer, wherein the concentration of the first conductivity type impurity in the first conductivity type first silicon carbide region increases in the thickness direction of the silicon carbide layer extending away from the gate electrode;
a second conductivity type second silicon carbide region located adjacent to the first conductivity type first silicon carbide region, wherein the second conductivity type second silicon carbide region contains the first conductivity type impurities and second conductivity type impurities, wherein the concentration of the first conductivity type impurity in the second conductivity type second silicon carbide region increases in the thickness direction of the silicon carbide layer in the direction extending away from the gate electrode; and
a second conductivity type third silicon carbide region, wherein the first conductivity type first silicon carbide region is located between the second conductivity type second silicon carbide region and the second conductivity type third silicon carbide region, wherein the second conductivity type third silicon carbide region contains the first conductivity type impurities and the second conductivity type impurities, and wherein the concentration of the first conductivity type impurity in the second conductivity type third silicon carbide region increases in the thickness direction of the silicon carbide layer extending in the direction away from the gate electrode.

2. The semiconductor device according to claim 1, wherein the concentration of the first conductivity type impurity in the second conductivity type second silicon carbide region and the second conductivity type third silicon carbide region continuously increases in the thickness direction of the silicon carbide layer extending in the direction away from the gate electrode.

3. The semiconductor device according to claim 1, wherein the concentration of the first conductivity type impurity in the second conductivity type second silicon carbide region and the section conductivity type third silicon carbide region increases in discrete steps of increased concentration in the thickness direction of the silicon carbide layer extending in the direction away from the gate electrode.

4. The semiconductor device according to claim 1, wherein the silicon carbide layer further comprises a first conductivity type fourth region contacting the second electrode, wherein the concentration of the first conductivity type impurity in the first conductivity type fourth region is greater than the concentration of the first conductivity type impurity in the first conductivity type first region.

5. The semiconductor device according to claim 1, wherein the silicon carbide layer further comprises a second conductivity type fifth region interposed between the second conductivity type second region and the gate insulating layer, and wherein the second conductivity type fifth region is interposed between the second conductivity type second region and the first electrode.

6. The semiconductor device according to claim 5, wherein the silicon carbide layer further comprises a second conductivity type sixth region interposed between the second conductivity type fifth region and the first electrode, and wherein the concentration of the second type impurity in the sixth region is greater than that of the second region.

7. The semiconductor device according to claim 6, wherein the silicon carbide layer further comprises a first conductivity type seventh region interposed between the second conductivity type fifth region and the first electrode, and wherein the seventh region is interposed between the second conductivity type fifth region and the gate insulating layer.

8. The semiconductor device according to claim 1, wherein the silicon carbide layer further comprises an inter-layer insulation film located between the first electrode and the gate electrode.

9. The semiconductor device according to claim 1, wherein the silicon carbide layer further comprises a first conductivity type eighth region interposed between and contacting the first, second and third regions and the fourth region, wherein the concentration of the first type impurities in the first conductivity type eighth region and the concentration of the first type impurity in the portion of the second region contacting the eighth region are the same.

10. The semiconductor device according to claim 1, wherein the concentration of the second conductivity type impurity in the second conductivity type second and third silicon carbide regions is uniform in the thickness direction of the silicon carbide layer in the direction extending away from the gate electrode.

11. A semiconductor device, comprising:
a first electrode;
a second electrode;
a silicon carbide layer, at least a portion of which is located between the first and second electrodes;
a gate electrode, wherein at least a portion of the silicon carbide layer is located between the gate electrode and the second electrode; and
a gate insulation film located between the gate electrode and the silicon carbide layer,
wherein the silicon carbide layer comprises:
a first conductivity type first silicon carbide region extending from the gate insulating film inwardly of the silicon carbide layer;
a second conductivity type second silicon carbide region located adjacent to the first conductivity type first silicon carbide region, wherein the second conductivity type second silicon carbide region contains the first conductivity type impurities and second conductivity type impurities, wherein the second conductivity type silicon carbide region includes at least a first sublayer and a second sublayer located between the first electrode and the first sublayer, and wherein the concentration of the first conductivity type impurity in the second sublayer is smaller than that in the first sublayer; and
a second conductivity type third silicon carbide region, wherein the first conductivity type first silicon carbide region is interposed between the second conductivity type second and third silicon carbide regions, wherein the second conductivity type third silicon carbide region contains the first conductivity type impurities and the second conductivity type impurities, wherein the second conductivity type silicon carbide region includes at least a third sublayer and a fourth sublayer located between the first electrode and the third sublayer, and wherein the concentration of the first conductivity type impurity in the fourth sublayer is smaller than that in the third sublayer.

12. The semiconductor device according to claim 11, wherein the concentration of the first conductivity type impurity in the first sublayer is constant.

13. The semiconductor device according to claim 11, wherein the concentration of the first conductivity type impurity in the first sublayer changes over the depth of the first sublayer.

14. The semiconductor device according to claim 11, wherein the gate electrode is interposed between the first electrode and the silicon carbide layer.

15. The semiconductor device according to claim 14, wherein the first silicon carbide region is interposed between the gate electrode and the second electrode.

16. A semiconductor device, comprising:
a first electrode;
a second electrode;
a silicon carbide layer having a plurality of alternately spaced first regions and second regions, at least a portion of which are located between the first and second electrodes;
a gate electrode, located over a first region of the silicon carbide layer; and
agate insulation film located between the gate electrode and the first region, wherein:
the concentration of a first conductivity type impurity in the first region and the second region of the silicon carbide layer increases in the direction of the second electrode; and
the second region further includes a second conductivity type impurity therein.

17. The semiconductor device according to claim 16, wherein the concentration of the first conductivity type impurity in the first and second regions changes in discrete steps in the direction from the first electrode to the second electrode.

18. The semiconductor device according to claim 16, wherein the concentration of the first conductivity type impurity in the first and second regions changes in a continuous manner in the direction from the first electrode to the second electrode.

19. The semiconductor device according to claim 16, wherein the concentration of the second conductivity type impurity in the second region is uniform in the direction from the first electrode to the second electrode.

20. The semiconductor device according to claim 16, wherein a portion of the first region contacts the gate insulating film.
